(19) United States
(12) Patent Application Publication
(10) Pub. No.: US 2024/0405506 A1
(43) Pub. Date: Dec. 5, 2024

(54) LIGHT-EMITTING MODULE, MOUNTING SUBSTRATE, AND MANUFACTURING METHOD OF MOUNTING SUBSTRATE

(71) Applicant: NICHIA CORPORATION, Anan-shi (JP)

(72) Inventor: Daisuke KASAI, Tokushima-shi (JP)

(21) Appl. No.: 18/673,150

(22) Filed: May 23, 2024

(30) Foreign Application Priority Data
May 31, 2023 (JP) 2023-090510

(51) Int. Cl. H01S 5/02315; H01S 5/024; H01S 5/042

(52) U.S. Cl. CPC H01S 5/02315; H01S 5/02469; H01S 5/04256

(57) ABSTRACT

A light-emitting module includes a mounting substrate and a light-emitting device. The mounting substrate includes first and second mounting portions and an insulating portion. The first mounting portion has a first upper surface. The second mounting portion has a second upper surface at a position higher than a position of the first upper surface. The insulating portion covers only a part of a region of the first upper surface, only a part of a region of the second upper surface, and a region between the first upper surface and the second upper surface. The light-emitting device has a lower surface mounted on the mounting substrate so as to overlap with at least a part of the first mounting portion, at least a part of the second mounting portion, and at least a part of the insulating portion in a top view.

### CROSS-REFERENCE TO RELATED APPLICATION

This application claims priority to Japanese Patent Application No. 2023-090510, filed on May 31, 2023, the disclosure of which is hereby incorporated by reference in its entirety.

### TECHNICAL FIELD

The present disclosure relates to a light-emitting module, a mounting substrate, and a manufacturing method of the mounting substrate.

### BACKGROUND

Japanese Patent Publication No. 2023-23889 A discloses a circuit board including a first substrate having a protruding post portion formed on an upper surface side of the first substrate and a metal layer provided on the first substrate via an insulating base material. The metal layer is insulated from the post portion.

### SUMMARY

It is an object of the present disclosure to disclose a structure of a mounting substrate in which a defect in an insulating property is less likely to occur when manufacturing the mounting substrate.

A light-emitting module disclosed in embodiments includes a mounting substrate and a light-emitting device. The mounting substrate includes a first mounting portion, a second mounting portion, and an insulating portion. The first mounting portion has a first upper surface. The second mounting portion is spaced apart from the first upper surface and has a second upper surface at a position higher than a position of the first upper surface. The insulating portion is arranged between the first upper surface and the second upper surface. The insulating portion covers only a part of a region of the first upper surface, only a part of a region of the second upper surface, and a region between the first upper surface and the second upper surface. The light-emitting device has a lower surface mounted on the mounting substrate so as to overlap with at least a part of the first mounting portion, at least a part of the second mounting portion, and at least a part of the insulating portion in a top view.

A mounting substrate disclosed in the embodiments includes a first mounting portion, a second mounting portion, and an insulating portion. The first mounting portion has a first upper surface. The second mounting portion is spaced apart from the first upper surface and has a second upper surface at a position higher than a position of the first upper surface. The insulating portion is arranged between the first upper surface and the second upper surface. The insulating portion covers only a part of a region of the first upper surface, only a part of a region of the second upper surface, and a region between the first upper surface and the second upper surface.

A manufacturing method of a mounting substrate disclosed in the embodiments includes: preparing a base material including a first mounting portion having a first upper surface and a second mounting portion spaced apart from the first upper surface and having a second upper surface at a position higher than a position of the first upper surface; and providing an insulating portion between the first upper surface and the second upper surface, the insulating portion covering only a part of a region of the first upper surface, only a part of a region of the second upper surface, and a region between the first upper surface and the second upper surface.

According to at least one of the embodiments in the present disclosure, a mounting substrate in which a defect in an insulating property is less likely to occur when manufacturing the mounting substrate can be realized.

### BRIEF DESCRIPTION OF DRAWINGS

FIG. 1 is a perspective view of a light-emitting module according to each embodiment.

FIG. 2 is a perspective view of a light-emitting device according to each embodiment.

FIG. 3 is a side view of the light-emitting device according to each embodiment.

FIG. 4 is a cross-sectional view of the light-emitting device taken along line IV-IV in FIG. 2.

FIG. 5 is a perspective view illustrating components disposed in an internal space of the light-emitting device according to each embodiment.

FIG. 6 is a top view of the state in FIG. 5.

FIG. 7 is a perspective view of a package of the light-emitting device according to each embodiment.

FIG. 8 is a cross-sectional view of the package taken along line VIII-VIII in FIG. 7.

FIG. 9 is a top view of a base of the package according to each embodiment.

FIG. 10 is a bottom view of the base according to each embodiment.

FIG. 11 is a cross-sectional view of the base taken along line XI-XI in FIG. 9.

FIG. 12 is a top view of a state in which a light-emitting element and a protective element are disposed on a submount.

FIG. 13 is a side view of the state in FIG. 12.

FIG. 14 is a top view of a wiring substrate according to each embodiment.

FIG. 15A is a cross-sectional view of a wiring substrate to be compared with the wiring substrate according to each embodiment.

FIG. 15B is a cross-sectional view of a wiring substrate according to a first embodiment, and is a cross-sectional view taken along line XVB-XVB in FIG. 14.

FIG. 15C is a cross-sectional view of the wiring substrate according to the first embodiment, and is a cross-sectional view taken along line XVC-XVC in FIG. 14.

FIG. 16A is a top view of a state in which a heat dissipation member is prepared for manufacturing the wiring substrate according to each embodiment.

FIG. 16B is a top view of a state in which first insulating members and electrode members are disposed on the heat dissipation member for manufacturing the wiring substrate according to each embodiment.

FIG. 17 is a cross-sectional view of a wiring substrate according to a second embodiment, and is a cross-sectional view taken along line XVII-XVII in FIG. 14.

### DETAILED DESCRIPTIONS

In the present description or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present description and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the description or the scope of the claims, descriptions such as upper and lower (upward/downward), left and right, surface and reverse, front and back (forward/backward), and near and far are used merely to describe the relative relationship of positions, orientations, directions, and the like, and the expressions need not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with an X, Y, and Z are the positive directions, and the opposite directions are the negative directions. For example, the direction marked with an X at the tip of the arrow is the X direction and the positive direction. In the present description, the direction, which is the X direction and is the positive direction, will be referred to as the “positive direction of X” and the direction opposite to this will be referred to as the “negative direction of X”. The term “X direction” includes both the positive direction and the negative direction. The same applies to the Y direction and Z direction.

In addition, in the present description, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including more than one object.

In addition, in the present description, a description describing “one or each of” objects is a description summarizing a description of one object in an embodiment including the one object, a description of one object in an embodiment including a plurality of the objects, and a description of each of a plurality of objects in an embodiment including the plurality of objects. Thus, the description describing “one or each of” objects supports every case of an embodiment including at least one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe a component or the like in the present description. The term “member” refers to an object physically treated alone. The object physically treated alone can be an object treated as one part in a manufacturing step. On the other hand, the term “portion” refers to an object that need not be physically treated alone. For example, the term “portion” is used when part of one member is partially considered, a plurality of members are collectively considered as one object, or the like.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present description and the claims, when a plurality of components are present and these components are to be indicated separately, the components may be distinguished by adding the terms “first” and “second” at the beginning of the names of the components. Objects to be distinguished may differ between the present description and the claims. Thus, even when a component in the claims is given the same term as that in the present description, the object identified by that component is not the same across the present description and the claims in some cases.

For example, when components distinguished by being termed “first”, “second”, and “third” are present in the present description, and when components given the terms “first” and “third” in the present description are described in the claims, these components may be distinguished by being denoted as “first” and “second” in the claims for ease of understanding. In this case, the components denoted as “first” and “second” in the claims refer to the components termed “first” and “third” in the present description, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments. That is, the embodiments illustrated by the drawings are not the only form in which the present invention is realized. Sizes, positional relationships, and the like of members illustrated in each of the drawings may sometimes be exaggerated in order to facilitate understanding.

### FIRST EMBODIMENT

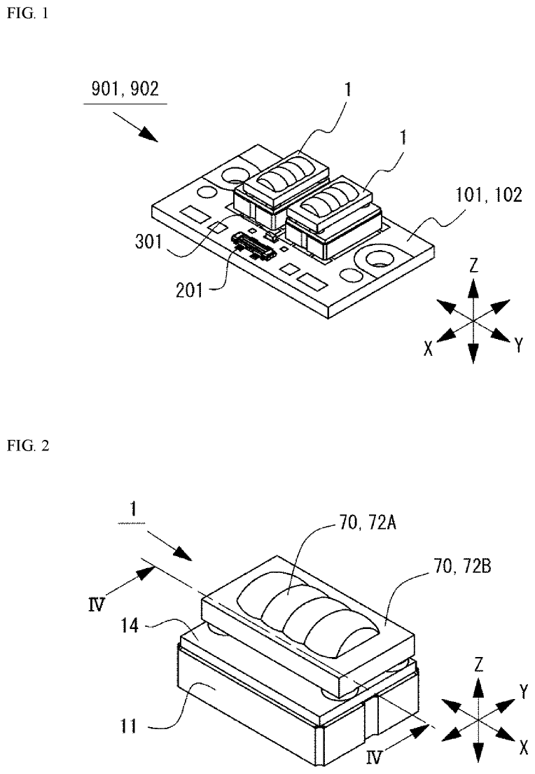

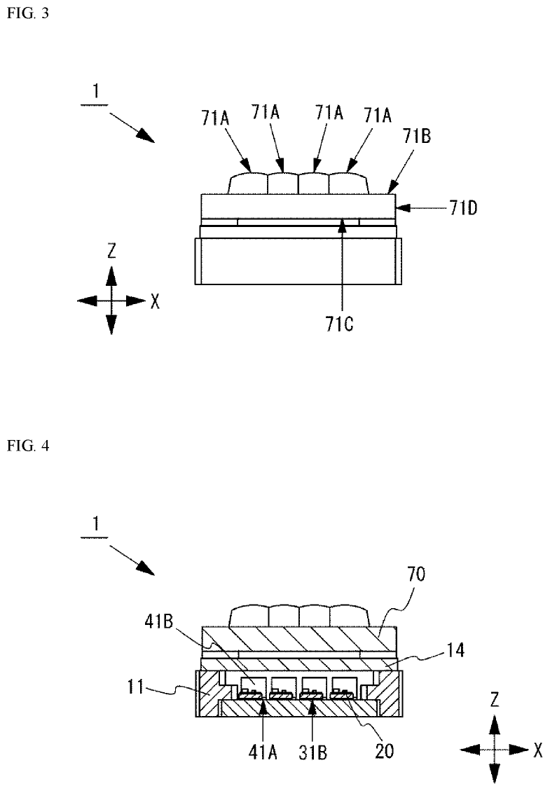

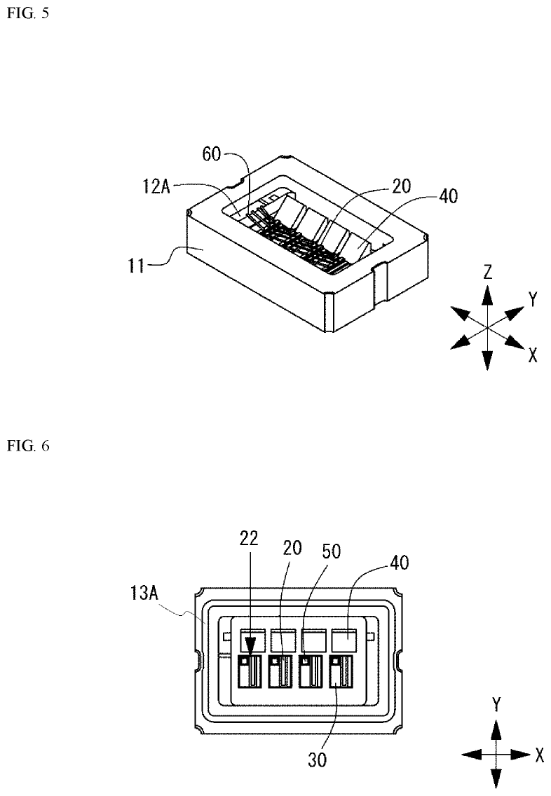

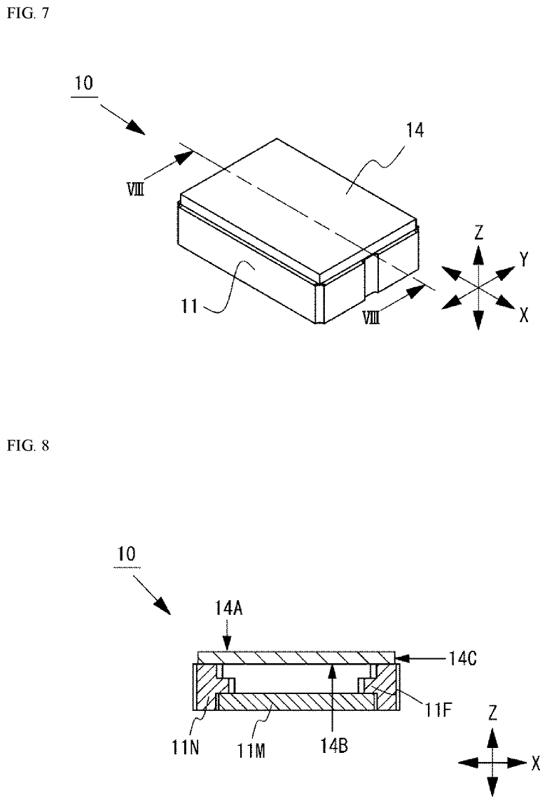

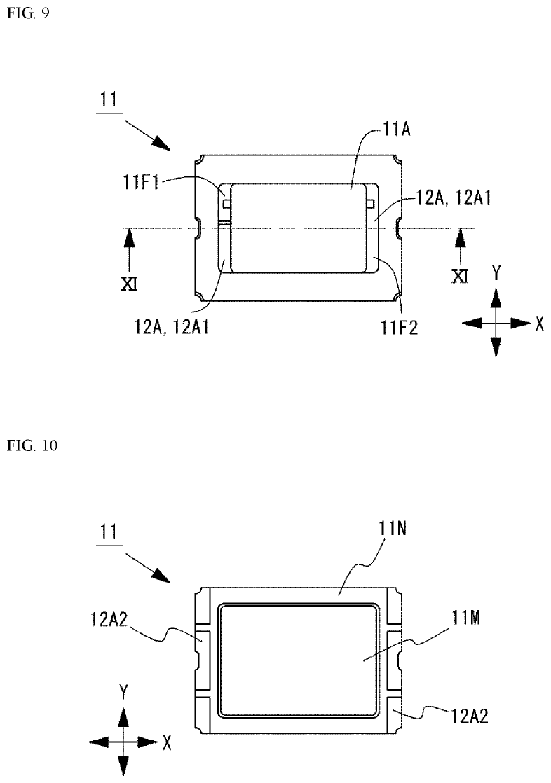

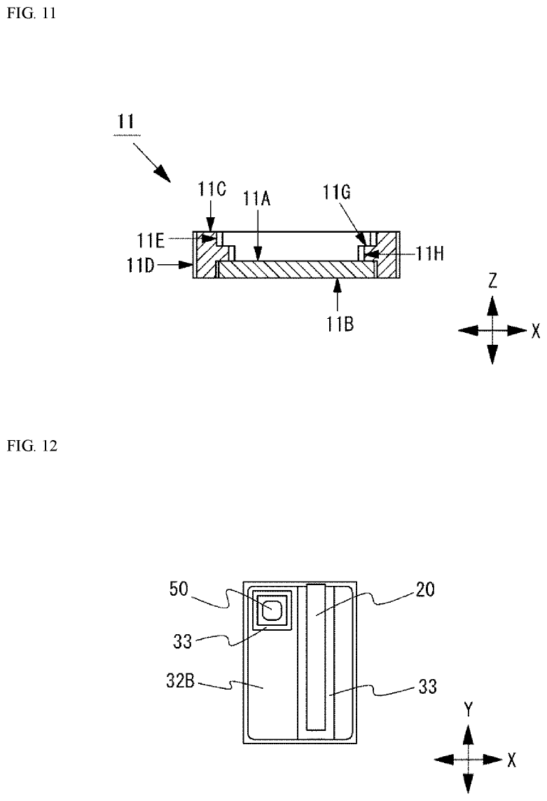

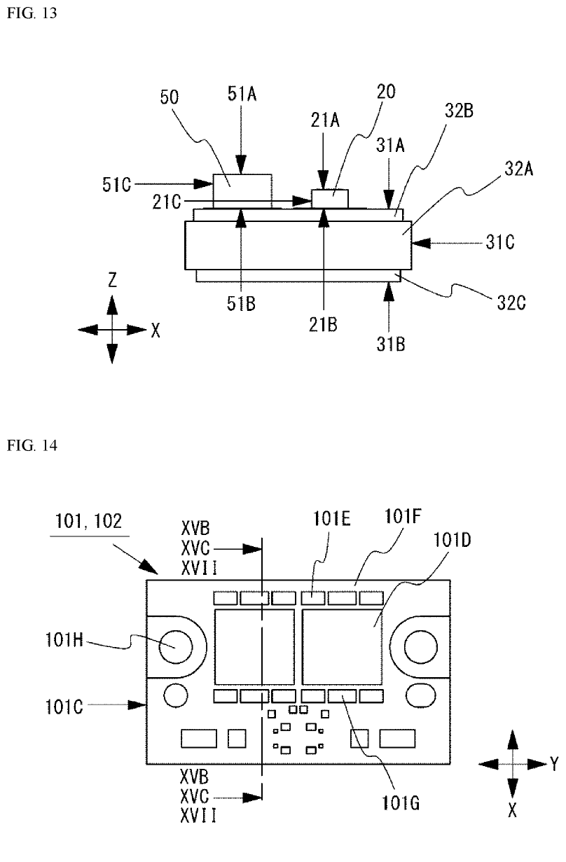

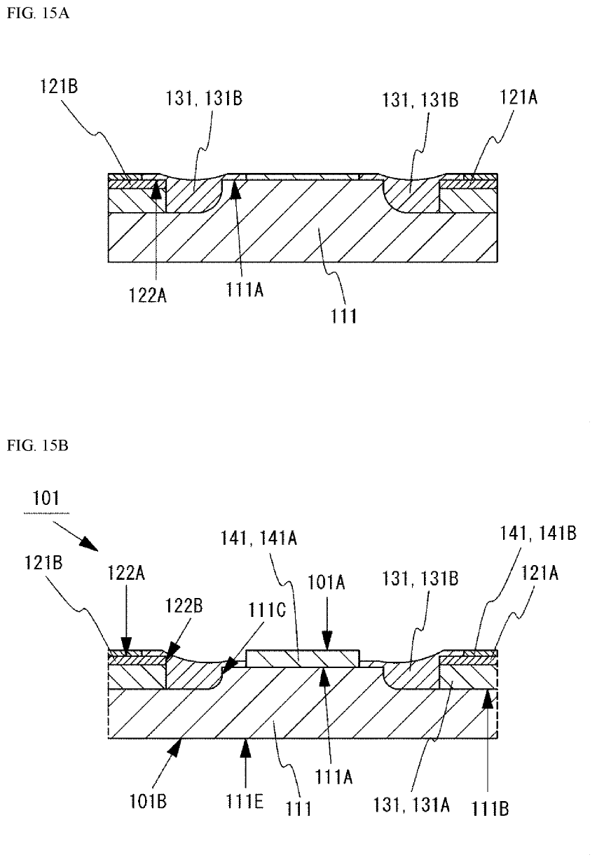

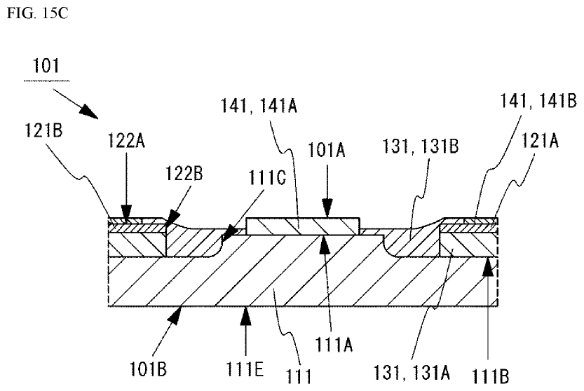

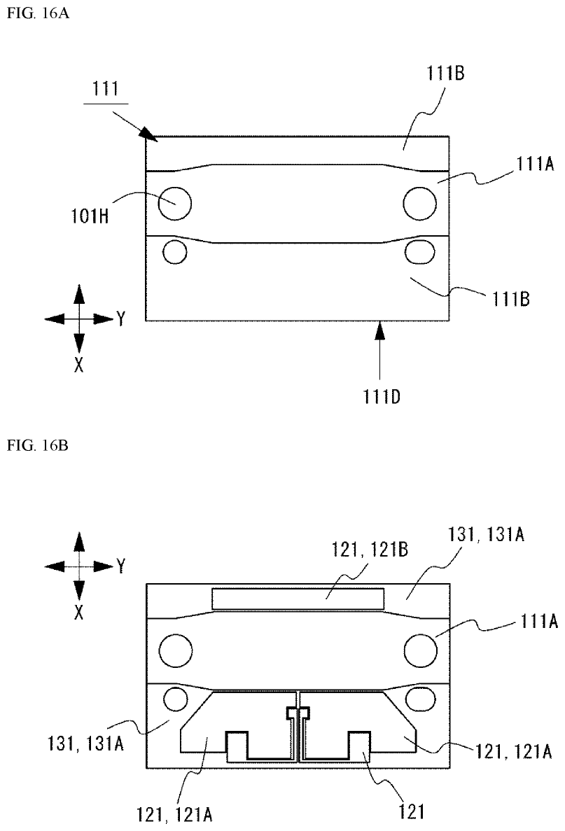

A light-emitting module 901 according to a first embodiment will be described. FIGS. 1 to 16B are drawings for describing an exemplary form of the light-emitting module 901. FIG. 1 is a perspective view of the light-emitting module 901. FIG. 2 is a perspective view of a light-emitting device 1. FIG. 3 is a side view of the light-emitting device 1. FIG. 4 is a cross-sectional view of the light-emitting device 1 taken along line IV-IV in FIG. 2. FIG. 5 is a perspective view illustrating components disposed in an internal space of the light-emitting device 1. FIG. 6 is a top view of the state in FIG. 5. Note that, in FIG. 6, wiring lines 60 illustrated in FIG. 5 are omitted. FIG. 7 is a perspective view of a package 10 of the light-emitting device 1. FIG. 8 is a cross-sectional view of the package 10 taken along line VIII-VIII in FIG. 7. FIG. 9 is a top view of a base 11 of the package 10. FIG. 10 is a bottom view of the base 11. FIG. 11 is a cross-sectional view of the base 11 taken along line XI-XI in FIG. 9. FIG. 12 is a top view of a state in which a light-emitting element 20 and a protective element 50 are disposed on a submount 30. FIG. 13 is a side view of the state in FIG. 12. FIG. 14 is a top view of a wiring substrate 101. FIG. 15A is a cross-sectional view of a wiring substrate to be compared with the wiring substrate 101. FIG. 15B is a cross-sectional view of the wiring substrate 101, and a cross-sectional view taken along line XVB-XVB in FIG. 14A. FIG. 15C is another example of a cross-sectional view of the wiring substrate 101, and a cross-sectional view taken along line XVC-XVC in FIG. 14. Note that, in FIGS. 15B and 15C, a first upper surface 111A of a heat dissipation member 111 and electrode members 121 disposed around the first upper surface 111A are mainly illustrated, and a cross-sectional view taken along the line XVB-XVB or the line XVC-XVC over the entire length of the wiring substrate 101 is not illustrated. FIG. 16A is a top view of a state in which the heat dissipation member 111 is prepared for manufacturing the wiring substrate 101. FIG. 16B is a top view of a state in which first insulating members 131A and the electrode members 121 are disposed on the heat dissipation member 111 for manufacturing the wiring substrate 101. Note that FIGS. 14 and 15B can be said to be a top view and a cross-sectional view of a state in which a second insulating member 131B and metal layers 141 are further disposed from the state of FIG. 16B for manufacturing the wiring substrate 101.

The light-emitting module 901 includes a plurality of components. The plurality of components included in the light-emitting module 901 include one or more of the light-emitting devices 1, the wiring substrate 101, a connector 201, and a thermistor 301.

The light-emitting module 901 may also include a component other than these components. For example, the light-emitting module 901 may include a light-emitting device different from the light-emitting device 1. The light-emitting module 901 need not include some of the plurality of components described above.

The light-emitting device 1 includes a plurality of components. The plurality of components include the package 10, one or more of the light-emitting elements 20, one or more of the submounts 30, one or more reflective members 40, one or more of the protective elements 50, a plurality of the wiring lines 60, and an optical member 70.

The light-emitting device 1 may include a component other than the components described above. For example, the light-emitting device 1 may further include a light-emitting element different from the one or more light-emitting elements 20. The light-emitting device 1 need not include some of the components described above.

First, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. The first upper surface 11A of the package 10 is a part of a region defining the internal space. In addition, each inner lateral surface 11E and the lower surface 14B of the package 10 are a part of the region defining the internal space.

The base 11 has a first upper surface 11A and a lower surface 11B. The base 11 has a second upper surface 11C. The base 11 has one or more outer lateral surfaces 11D. The base 11 has one or more of the inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion.

The base 11 includes one or more step portions 11F. The step portion 11F includes an upper surface 11G and a lateral surface 11H that meets the upper surface 11G and extends downward from the upper surface 11G. Here, one step portion 11F only has one upper surface 11G and one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. The one or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The description of “perpendicular” here allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

The base 11 includes a base portion 11M and a frame portion 11N. The base portion 11M and the frame portion 11N may be members made of mutually different materials. The base 11 can be configured to include a base member corresponding to the base portion 11M and a frame member corresponding to the frame portion 11N.

The base portion 11M includes the first upper surface 11A. The frame portion 11N includes the second upper surface 11C. The frame portion 11N includes the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The plurality of wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. The one or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, the one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as the main material, for example. Examples of the ceramic as the main material of the base 11 include aluminum nitride, silicon nitride, aluminum oxide, or silicon carbide.

Here, the main material refers to a material that occupies the greatest proportion of a target formed product in terms of mass or volume. When a target formed product is formed of a single material, that material is the main material. In other words, when a certain material is the main material, the proportion of that material may be 100%.

The base 11 may be formed using a base member and a frame member formed using main materials different from each other. The base member can be formed using a main material with an excellent heat dissipating property, for example, a metal or a composite containing a metal, graphite, or diamond. Examples of the metal as the main material of the base member include, for example, copper, aluminum, or iron. Examples of a compound containing the metal as the main material of the base member include, for example, copper-molybdenum or copper-tungsten. The frame member can be formed using, as the main material, for example, any of the above mentioned ceramics given as examples of the main material of the base 11.

The wiring portion 12A can be formed using a metal material as the main material, for example. Examples of the metal material as the main material of the wiring portion 12A include a single-component metal, such as Cu, Ag, Ni, Au, Ti, Pt, Pd, Cr, and W, or an alloy containing any of these metals. The wiring portion 12A can be constituted by one or more metal layers, for example.

The bonding pattern 13A can be formed using a metal material as the main material, for example. Examples of the metal material as the main material of the bonding pattern 13A include a single-component metal, such as Cu, Ag, Ni, Au, Sn, Ti, and Pd, or an alloy containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed in a rectangular parallelepiped flat plate shape. The shape thereof need not be the rectangular parallelepiped shape.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 has light transmissivity to transmit light. Here, “having light transmissivity” means that the transmittance with respect to light that is incident on the lid body 14 is equal to or more than 80%. The lid body 14 may partially include a non-light transmitting region (a region with no light transmissivity).

The lid body 14 can be formed using glass as the main material, for example. The lid body 14 can also be formed using sapphire as the main material, for example.

### Light-Emitting Element 20

The light-emitting element 20 has an upper surface 21A, a lower surface 21B, and a plurality of lateral surfaces 21C. The shape of the upper surface 21A is rectangular. The rectangular shape is a rectangular shape having long sides and short sides. The outer shape of the light-emitting element 20 in a top view is rectangular. The rectangular shape is a rectangular shape having long sides and short sides. The shape of the upper surface 21A and the outer shape of the light-emitting element 20 in a top view are not limited thereto.

The light-emitting element 20 has a light-emitting surface 22 from which light is emitted. For example, the lateral surface 21C can be the light-emitting surface 22. The lateral surface 21C serving as the light-emitting surface 22 meets a short side of the upper surface 21A. Also, for example, the upper surface 21A can be the light-emitting surface 22. The light-emitting element 20 has one or more of the light-emitting surfaces 22.

As the light-emitting element 20, for example, a light-emitting element that emits blue light can be employed. Also, for example, as the light-emitting element 20, a light-emitting element that emits green light can be employed. Also, for example, as the light-emitting element 20, a light-emitting element that emits red light can be employed. As the light-emitting element 20, a light-emitting element that emits light of another color or another wavelength may be employed.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the light-emitting element 20 that emits blue light or the light-emitting element 20 that emits green light include a light-emitting element containing a nitride semiconductor. A GaN-based semiconductor, such as GaN, InGaN, and AlGaN, for example, can be employed as the nitride semiconductor. Examples of the light-emitting element 20 that emits red light include a light-emitting element containing an InAlGaP-based semiconductor, a GaInP-based semiconductor, or a GaAs-based semiconductor, such as GaAs and AlGaAs.

As the light-emitting element 20, for example, a semiconductor laser element can be employed. As the light-emitting element 20, a single emitter-semiconductor laser element constituted by one emitter can be employed. Also, as the light-emitting element 20, a multi-emitter semiconductor laser element constituted by a plurality of emitters can be employed. The light-emitting element 20 is not limited to a semiconductor laser element, and a light-emitting diode or the like may be employed.

Here, a semiconductor laser element being an example of the light-emitting element 20 will be described.

The semiconductor laser element emits a directional laser beam. Spreading divergent light is emitted from the light-emitting surface 22 of the semiconductor laser element. The light emitted from the semiconductor laser element forms a far-field pattern (hereinafter, referred to as an “FFP”) with an elliptical shape in a plane parallel to the light-emitting surface 22. The FFP indicates a shape and a light intensity distribution of the emitted light at a position separated from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to a peak intensity value is referred to as a main portion of the light.

The shape of the FFP of the light emitted from the semiconductor laser element is an elliptical shape in which the light is longer in a layering direction than in a direction perpendicular to the layering direction in the plane parallel to the light-emitting surface 22. The layering direction is a direction in which a plurality of semiconductor layers including an active layer are layered in the semiconductor laser element. The direction perpendicular to the layering direction can also be referred to as a plane direction of the semiconductor layer. Further, a long diameter direction of the elliptical shape of the FFP can also be referred to as a fast axis direction of the semiconductor laser element, and a short diameter direction can also be referred to as a slow axis direction of the semiconductor laser element.

Based on the light intensity distribution of the FFP, an angle at which light having a light intensity of 1/e² of a peak light intensity spreads is referred to as a divergence angle of light of the semiconductor laser element. Here, the divergence angle of light is indicated as an angle formed by light having a peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element can be in a range from 20 degrees to less than 80 degrees. Also, the divergence angle of the light in the slow axis direction can be in a range from more than 0 degrees to 20 degrees. Also, the divergence angle of the light in the fast axis direction is greater than the divergence angle of the light in the slow axis direction.

For example, the divergence angle in the fast axis direction of the blue light emitted from the semiconductor laser element can be in a range from 30 degrees to less than 60 degrees, and the divergence angle in the slow axis direction can be in a range from 5 degrees to less than 20 degrees. Also, for example, the divergence angle in the fast axis direction of the green light emitted from the semiconductor laser element can be in a range from 30 degrees to less than 60 degrees, and the divergence angle in the slow axis direction can be in a range from 5 degrees to less than 20 degrees. Also, for example, the divergence angle in the fast axis direction of the red light emitted from the semiconductor laser element can be in a range from 40 degrees to less than 80 degrees, and the divergence angle in the slow axis direction can be in a range from 5 degrees to less than 20 degrees.

### Submount 30

The submount 30 includes an upper surface 31A, a lower surface 31B, and one or more lateral surfaces 31C. It can be said that the upper surface 31A is a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the illustrated submount 30, the lateral direction is the same direction as the X direction, and the longitudinal direction is the same direction as the Y direction.

The submount 30 can comprise a substrate 32A and an upper metal member 32B. The submount 30 can further comprise a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with a relatively good heat dissipating property (having high thermal conductivity) as the main material of the substrate 32A.

A metal, such as copper and aluminum, is used as the main material of the upper metal member 32B. The upper metal member 32B has one or more metal layers. The upper metal member 32B can have a plurality of metal layers formed of different metals as main materials.

A metal, such as copper or aluminum, is used as the main material of the lower metal member 32C. The lower metal member 32C has one or more metal layers. The lower metal member 32C can have a plurality of metal layers formed of different metals as main materials.

The wiring layer 33 can be formed using a metal. For example, the wiring layer 33 can be formed using AuSn solder (a metal layer of AuSn).

For example, the length of the submount 30 in the short-side direction or the lateral direction is in a range from 300 μm to 2000 μm. The length of the submount 30 in the long-side direction or the longitudinal direction is in a range from 500 μm to 10000 μm. The difference between the length of the submount 30 in the longitudinal direction and the length in the lateral direction is in a range from 200 μm to 9000 μm.

For example, the thickness of the submount 30 (the width in a direction perpendicular to the upper surface 31A) is in a range from 100 μm to 500 μm. Also, for example, the thickness of the substrate 32A is in a range from 100 μm to 400 μm. Also, for example, the thickness of the upper metal member 32B is in a range from 0 μm to 200 μm. Also, for example, the thickness of the lower metal member 32C is in a range from 0 μm to 200 μm. Also, for example, the thickness of the wiring layer 33 is in a range from 0.1 μm to 5 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass, metal, or the like can be used. A heat-resistant material is preferably used as the main material of the reflective member 40. As the main material, for example, a glass, such as quartz glass or borosilicate glass (BK7), or a metal, such as Al, can be used. The reflective member 40 can also be formed using Si as the main material.

When the main material is a reflective material, such as Al, the light-reflective surface 41B can be formed of the main material. Instead of forming the light-reflective surface 41B with the main material, the general shape of the reflective member 40 may be formed with the main material, and the light-reflective surface 41B may be formed on a surface of the general shape. In this case, the light-reflective surface 41B can be formed using, for example, a metal layer, such as Ag or Al, or a dielectric multilayer film of Ta₂O₅/SiO₂, TiO₂/SiO₂, Nb₂O₅/SiO₂ or the like.

In the light-reflective surface 41B, the reflectance with respect to the peak wavelength of the light emitted on the light-reflective surface 41B is equal to or more than 90%. The reflectance may be equal to or more than 95%. The reflectance can be equal to or more than 99%. The light reflectance is equal to or less than 100% or is less than 100%.

### Protective Element 50

The protective element 50 has an upper surface 51A, a lower surface 51B, and one or more lateral surfaces 51C. The shape of the protective element 50 is a rectangular parallelepiped. The shape of the protective element 50 need not be a rectangular parallelepiped.

The protective element 50 inhibits breakage of a specific element (the light-emitting element 20, for example) as a result of an excessive current flowing through the element. The protective element 50 is a Zener diode, for example. A Zener diode formed of Si can be used as the Zener diode.

### Wiring Line 60

The wiring line 60 is a linear conductive material with bonded portions at both ends. The bonded portions at both ends are bonded portions with other components. The wiring line 60 is, for example, a metal wire. For example, gold, aluminum, silver, copper, or the like can be used as the metal.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical active surface that imparts the optical action. The upper surface 71A, the lower surface 71B, or the lateral surface 71C can be the optical active surface. Alternatively, the optical active surface may be provided at a position different from the upper surface 71A, the lower surface 71B, or the lateral surface 71C. For example, the optical active surface may be formed not on a surface of the optical member 70 but on an inner side of the optical member 70.

The optical member 70 can have one or more lens surfaces 71D. The lens surface 71D is the optical active surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. Note that the lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

The outer shape of the optical member 70 in a top view is rectangular. Note that the outer shape of the optical member 70 in a top view need not be rectangular. The lower surface 71B is a flat surface. The lens surface 71D is not formed on the lower surface 71B side of the optical member 70. The shape of the lower surface 71B is rectangular. The shape of the lower surface 71B need not be rectangular.

In the optical member 70, a portion overlapping with the lens surface 71D in a top view is a lens portion 72A. In the optical member 70, a portion overlapping with the upper surface 71A in a top view is a non-lens portion 72B. The lower surface 71B has a region constituting the lower surface of one or each of the lens portions 72A and a region constituting the lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lens. In the illustrated optical member 70, the coupling direction is the same direction as the X direction.

The plurality of lens surfaces 71D are formed such that the vertices of the respective lens surfaces 71D are provided on one straight line. The imaginary straight line connecting the respective vertices is parallel to the lower surface 71B of the optical member 70. Note that the term “parallel” used here allows a difference within ±5 degrees.

The curvatures of two or more lens surfaces 71D, that is, some or all of the plurality of lens surfaces 71D can be the same. The plurality of lens surfaces 71D can all have the same curvatures.

The optical member 70 has light transmissivity. In the optical member 70, the light transmittance with respect to the peak wavelength of light incident on the optical member 70 is equal to or more than 80%. The optical member 70 may include a light-transmitting region with light transmissivity and a region with no light transmissivity (hereinafter, referred to as a non-light transmitting region). In the non-light-transmitting region, the light transmittance with respect to the peak wavelength of light incident on the optical member 70 is equal to or less than 50%. The optical member 70 can be formed using, for example, glass, such as BK7.

### Wiring Substrate 101

The wiring substrate 101 has an upper surface 101A, a lower surface 101B, and one or more lateral surfaces 101C. The wiring substrate 101 has a plate-like shape. The outer edge shape of the wiring substrate 101 in a top view is rectangular. This rectangular shape can be a rectangular shape with long sides and short sides. In the illustrated package 10, a short-side direction of the rectangular shape is the same direction as the X direction, and a long-side direction is the same direction as the Y direction.

The wiring substrate 101 includes heat dissipation portions 101D, electrode portions 101E, and an insulating portion 101F. The heat dissipation portion 101D functions as a heat dissipation path for heat generated from other components mounted on the wiring substrate 101. The electrode portion 101E is electrically connected to the other components mounted on the wiring substrate 101.

The insulating portion 101F insulates the heat dissipation portion 101D and the electrode portion 101E. The insulating portion 101F is provided to insulate electrical connection between the heat dissipation portion 101D and the electrode portion 101E in the wiring substrate 101.

The upper surface 101A of the wiring substrate 101 includes, among the heat dissipation portion 101D, the electrode portion 101E, and the insulating portion 101F, a region in which the heat dissipation portion 101D is at the uppermost position (hereinafter, referred to as a first region of the upper surface 101A), a region in which the electrode portion 101E is at the uppermost position (hereinafter, referred to as a second region of the upper surface 101A), and a region in which the insulating portion 101F is at the uppermost position (hereinafter, referred to as a third region of the upper surface 101A). On the upper surface 101A, the first region and the second region are spaced apart from each other by the third region.

The wiring substrate 101 includes the heat dissipation member 111 (one example of the first mounting portion in this embodiment), a plurality of the electrode members 121 (one example of the second mounting portion in this embodiment), and one or more insulating members 131 (one example of the insulating portion in this embodiment). The heat dissipation portion 101D includes the heat dissipation member 111, the electrode portion 101E includes the plurality of electrode members 121, and the insulating portion 101F includes the one or more insulating members 131.

The wiring substrate 101 includes one or more of the metal layers 141. The one or more metal layers 141 include one or more first metal layers 141A included in the heat dissipation portion 101D and one or more second metal layers 141B included in the electrode portion 101E.

The wiring substrate 101 is provided with one or more through holes 101H. The one or more through holes 101H include a through hole 101H used for fixing the wiring substrate 101 to another member (component). For example, a screw is fitted into the through hole 101H to fix the wiring substrate 101 to another member. The one or more through holes 101H include a through hole 101H used for determining positions when fixing the wiring substrate 101 to another member.

The heat dissipation member 111 has the first upper surface 111A (one example of the first upper surface of the first mounting portion in this embodiment). The heat dissipation member 111 has one or more second upper surfaces 111B at a position lower than the position of the first upper surface 111A. The heat dissipation member 111 has one or more first lateral surfaces 111C that meet the first upper surface 111A. The heat dissipation member 111 has one or more second lateral surfaces 111D that respectively meet the one or more second upper surfaces 111B. The heat dissipation member 111 has a lower surface 111E.

The heat dissipation member 111 includes a protruding portion protruding from one or each of the second upper surfaces 111B. The protruding portion has the first upper surface 111A and the one or more first lateral surfaces 111C. The height of the protruding portion of the heat dissipation member 111 (height from the second upper surface 111B to the first upper surface 111A) is smaller than the height from the lower surface 111E to the second upper surface 111B.

The outer edge shape of the heat dissipation member 111 in a top view is rectangular. The rectangular shape is a rectangular shape having long sides and short sides. In the illustrated heat dissipation member 111, the long-side direction is the same direction as the Y direction, and the short-side direction is the same direction as the X direction.

The one or more insulating members 131 are provided on the heat dissipation member 111. The one or more insulating members 131 include the first insulating member 131A provided on the one or more second upper surfaces 111B.

The plurality of electrode members 121 are provided on the first insulating members 131A. The plurality of electrode members 121 are provided in a plurality of regions spaced apart from each other. The heat dissipation member 111 and each of the electrode members 121 are spaced apart from each other. Each of the electrode members 121 is insulated from the heat dissipation member 111 via the first insulating member 131A.

The plurality of electrode members 121 include a first electrode member 121A and a second electrode member 121B. In a top view, the first upper surface 111A is disposed between the first electrode member 121A and the second electrode member 121B. In a top view, the first electrode member 121A, the first upper surface 111A, and the second electrode member 121B are disposed in this order.

Each of the electrode members 121 has an upper surface 122A (one example of the second upper surface of the second mounting portion in this embodiment) and one or more lateral surfaces 122B. In a top view, the first upper surface 111A of the heat dissipation member 111 and the upper surface 122A of each of the electrode members 121 are spaced apart from each other. One or each of the electrode members 121 has the lateral surface 122B opposed to the first lateral surface 111C of the heat dissipation member 111.

The one or more insulating members 131 include the second insulating member 131B provided between the heat dissipation member 111 and each of the electrode members 121. One or each of the first lateral surfaces 111C of the heat dissipation member 111 is covered by the second insulating member 131B. The lateral surface 122B of one or each of the electrode members 121 that is opposed to the first lateral surface 111C is covered by the second insulating member 131B. The second insulating member 131B fills a space between the first lateral surface 111C and the lateral surface 122B.

The upper surface 122A of the one or each of the electrode members 121 (one example of the second upper surface of the second mounting portion in this embodiment) is at a position higher than the position of the first upper surface 111A of the heat dissipation member 111 (one example of the first upper surface of the first mounting portion in this embodiment). The upper surface 122A is higher than the first upper surface 111A by an amount in a range from 30 μm to 150 μm.

The second insulating member 131B covers a part of the first upper surface 111A extending from the first lateral surface 111C of the heat dissipation member 111. The second insulating member 131B covers a part of the upper surface 122A extending from the lateral surface 122B of the electrode member 121.

The second insulating member 131B is provided to cover a region between the first upper surface 111A and the upper surface 122A, only a part of the region of the first upper surface 111A, and only a part of the region of the upper surface 122A. By providing a height difference between the first upper surface 111A and the upper surface 122A, it is possible to make the shape of the second insulating member 131B provided between the heat dissipation member 111 and the electrode member 121 into a shape that is less likely to cause a defect in the insulating property.

FIG. 15A schematically illustrates the second insulating member 131B formed when there is no height difference between the first upper surface 111A and the upper surface 122A. FIG. 15B schematically illustrates the shape of the second insulating member 131B formed when a height difference is provided between the first upper surface 111A and the upper surface 122A. A solder resist is used for the second insulating member 131B.

In the second insulating member 131B of FIG. 15A, a dent that is recessed downward from the first upper surface 111A and the upper surface 122A is formed between the first upper surface 111A and the upper surface 122A, and thereby a portion having a reduced thickness from the heat dissipation member 111 or from the electrode member 121 is generated. In the second insulating member 131B of FIG. 15B, an inclined surface is formed so as to rise from a lower side to a higher side between the first upper surface 111A and the upper surface 122A. Also, a dent is less likely to be generated than in FIG. 15A. Thus, compared with the former shape in which a dent is generated, the latter shape in which an inclined surface is formed is relatively less likely to generate a portion in which the thickness from the heat dissipation member 111 or from the electrode member 121 is reduced. Therefore, it can be said that the latter is a structure in which a defect in the insulating property due to manufacturing variation is less likely to occur.

The second insulating member 131B includes a first portion provided on the first upper surface 111A, a second portion provided on the upper surface 122A, and a third portion provided between the first upper surface 111A and the upper surface 122A. The upper surface of the third portion of the second insulating member 131B has an inclined surface region extending from the upper surface side of the first portion toward the upper surface side of the second portion. In the illustrated wiring substrate 101, the X direction can be said to be a direction extending from the upper surface side of the first portion toward the upper surface side of the second portion.

The upper surface of the second portion of the second insulating member 131B is higher than the upper surface of the first portion. The upper surface of the third portion of the second insulating member 131B has a height equal to or higher than the height of the upper surface of the first portion of the second insulating member 131B. By adjusting the height difference between the first upper surface 111A and the upper surface 122A, as illustrated in FIG. 15C, the second insulating member 131B can be formed such that the upper surface of the third portion of the second insulating member 131B does not have a region lower than the upper surface of the first portion of the second insulating member 131B.

In a top view, the distance from the first upper surface 111A to the upper surface 122A is in a range from 100 μm to 300 μm. By satisfying this distance, it becomes easy to use the height difference between the first upper surface 111A and the upper surface 122A to suppress the generation of a dent in the third portion of the second insulating member 131B. The distance from the first upper surface 111A to the upper surface 122A can also be said to be the distance from the first lateral surface 111C to the lateral surface 122B facing each other. Alternatively, the distance may be said to be the distance from the line of intersection between the first lateral surface 111C and the first upper surface 111A to the line of intersection between the lateral surface 122B and the upper surface 122A.

The distance from the boundary between the first upper surface 111A of the heat dissipation member 111 and the second insulating member 131B to the boundary between the upper surface 122A of the electrode member 121 and the second insulating member 131B is in a range from 300 μm to 500 μm.

The second insulating member 131B is partially provided on the electrode member 121 in a top view. Due to the second insulating member 131B, one continuous electrode member 121 appears to be divided into a plurality of regions.

The one or more metal layers 141 are provided on the heat dissipation member 111 or the electrode member 121. The first metal layer 141A is provided on the heat dissipation member 111. The second metal layer 141B is provided on the electrode member 121. The upper surface of the one or more metal layers 141 forms a part of the region of the upper surface 101A of the wiring substrate 101. The upper surface of the insulating member 131 forms another part of the region of the upper surface 101A of the wiring substrate 101.

One or each of the metal layers 141 is provided inside the second insulating member 131B in a top view. The heat dissipation portion 101D includes the first metal layer 141A. The electrode portion 101E includes the second metal layer 141B.

In the wiring substrate 101, the first metal layer 141A is thicker than the second metal layer 141B. The height difference between the upper surface of the first metal layer 141A and the upper surface of the second metal layer 141B is smaller than the height difference between the first upper surface 111A of the heat dissipation member 111 and the upper surface 122A of the electrode member 121. That is, by adjusting the thickness of the metal layers 141, the height difference between the upper surface of the heat dissipation portion 101D and the upper surface of the electrode portion 101E is reduced.

In the wiring substrate 101, the upper surface of the first metal layer 141A and the upper surface of the second metal layer 141B preferably have uniform height. That is, the height difference between the upper surface of the heat dissipation portion 101D and the upper surface of the electrode portion 101E is preferably zero, and the height difference that occurs within the range of manufacturing variation is allowed. For example, the height difference between the upper surface of the first metal layer 141A and the upper surface of the second metal layer 141B is preferably within ±20 μm.

As the main material of the heat dissipation member 111, a metal material can be used.

As the main material of the heat dissipation member 111, for example, a single-component metal, such as Cu, Ag, Al, Ni, Rh, Au, Ti, Pt, Pd, Mo, Cr, and W, or an alloy containing any of these metals can be used. The heat dissipation member 111 is preferably formed of a material with an excellent heat dissipating property. The heat dissipation member 111 can be formed containing 95 mass % or more of copper.

As the main material of the electrode member 121, a metal material can be used. As the main material of the electrode member 121, for example, a single-component metal, such as Cu, Ag, Al, Ni, Rh, Au, Ti, Pt, Pd, Mo, Cr, and W, or an alloy containing any of these metals can be used.

The insulating member 131 is formed of an insulating material. For example, polyimide can be used as the main material of the insulating member 131. Also, for example, as the main material of the insulating member 131, glass epoxy obtained by impregnating one or more glass cloths with a thermosetting insulating resin, such as an epoxy resin, and curing the thermosetting insulating resin, a liquid crystal polymer, or the like can be used. For example, film-like polyimide can be employed for the first insulating member 131A, and a resist, such as a solder resist, can be employed for the second insulating member 131B.

As the main material of the metal layer 141, a metal material, for example, Au, Ag, Cu, Pt, Ni, Pd, or an alloy containing one of these materials can be used. The metal layer 141 can be formed by performing a plating process.

The wiring substrate 101 can be manufactured by a manufacturing method including a step of preparing the heat dissipation member 111 (hereinafter, referred to as a first step), a step of providing the first insulating member 131A and the electrode member 121 on the heat dissipation member 111 (hereinafter, referred to as a second step), a step of providing the second insulating member 131B between the heat dissipation member 111 and the electrode member 121 (hereinafter, referred to as a third step), and a step of providing the metal layer 141 on the heat dissipation member 111 or the electrode member 121 (hereinafter, referred to as a fourth step). Note that the first step to the fourth step are not intended to limit the manufacturing steps of the wiring substrate 101 to this order, but are supplementary notes for convenience.

In the first step, the heat dissipation member 111 is prepared.

In the second step, the first insulating member 131A is provided on the second upper surface 111B of the heat dissipation member 111. In addition, one or more of the electrode members 121 are provided on the first insulating member 131A. In the second step, a plurality of the electrode members 121 including one or more of the first electrode members 121A and one or more of the second electrode members 121B are disposed on the second upper surface 111B.

The upper surface 122A of the first electrode member 121A provided on the second upper surface 111B in the second step is at a position higher than the position of the first upper surface 111A of the heat dissipation member 111. The upper surface 122A of the second electrode member 121B provided on the second upper surface 111B in the second step is at a position higher than the position of the first upper surface 111A of the heat dissipation member 111.

The first insulating member 131A may be provided on the second upper surface 111B after the electrode member 121 is provided on the first insulating member 131A. The first insulating member 131A is interposed between the second upper surface 111B and the electrode member 121.

A base material in a state in which the first step and the second step have been performed may be prepared. Also, the electrode member 121 need not be disposed on the second upper surface 111B. For example, the heat dissipation member and the electrode member can be spaced apart from each other to be disposed on different components. In such an embodiment, the first insulating member 131A might be unnecessary.

Therefore, the first step and the second step can be replaced with a step of preparing a base metal including the heat dissipation member 111 having the first upper surface 111A and the one or more electrode members 121 spaced apart from the first upper surface 111A and having the upper surface 122A at a position higher than the position of the first upper surface 111A.

In the third step, the second insulating member 131B is provided between the first upper surface 111A of the heat dissipation member 111 and the upper surface 122A of the electrode member 121 in a top view. In addition, the second insulating member 131B is provided on a part of the region of the first upper surface 111A and on a part of the region of the upper surface 122A in a top view. According to the third step, the space between the first lateral surface 111C of the heat dissipation member 111 and the lateral surface 122B of the electrode member 121 opposed to each other is filled by the second insulating member 131B.

By providing a height difference between the first upper surface 111A of the heat dissipation member 111 and the upper surface 122A of the electrode member 121, it is possible to make the shape of the second insulating member 131B filling a space between the first upper surface 111A and the upper surface 122A into a shape that is less likely to cause a defect in the insulating property as compared with when there is no height difference.

The larger the height difference is, the less likely a defect in the insulating property occurs, but a better heat dissipating property can be obtained when the height difference is not excessively large. The height difference between the first upper surface 111A and the upper surface 122A is preferably in a range from 30 μm to 150 μm.

In the fourth step, the first metal layer 141A is provided on the first upper surface 111A of the heat dissipation member 111. The first metal layer 141A is provided in a region of the first upper surface 111A in which the second insulating member 131B is not provided. The upper surface of the first metal layer 141A is at a position higher than the position of the upper surface of the second insulating member 131B provided on the first upper surface 111A. The height difference between the upper surface of the first metal layer 141A and the upper surface of the second insulating member 131B provided on the first upper surface 111A is equal to or less than 220 μm. Accordingly, the heat dissipating property of the wiring substrate 101 can be improved while maintaining the insulating property thereof.

In the fourth step, the second metal layer 141B is provided on the upper surface 122A of the electrode member 121. The second metal layer 141B is provided in a region of the upper surface 122A in which the second insulating member 131B is not provided. The upper surface of the second metal layer 141B and the upper surface of the second insulating member 131B provided on the upper surface 122A have the same height. The term “same height” used here allows a difference of ±50 μm. Accordingly, it is possible to achieve stable conduction with an object mounted on the electrode member 121 while maintaining the insulating property of the wiring substrate 101.

### Connector 201

The connector 201 has an insertion port into which a connector cable is inserted.

### Thermistor 301

The thermistor 301 can be used as an element for measuring temperatures.

Subsequently, the light-emitting module 901 will be described.

### Light-Emitting Module 901

In the light-emitting module 901, the one or more light-emitting devices 1 are mounted on the wiring substrate 101. The one or more light-emitting devices 1 are disposed on the upper surface 101A of the wiring substrate 101. The lower surface 11B of the light-emitting device 1 is bonded to the upper surface 101A of the wiring substrate 101 via an adhesive, such as AuSn solder.

On the wiring substrate 101, a plurality of the light-emitting devices 1 can be disposed in mutually different directions. In the illustrated light-emitting module 901, two light-emitting devices 1 are disposed so as to be turned 180° from each other in the XY plane. In the drawings related to the light-emitting device 1 and the drawings related to the light-emitting module 901, the XYZ directions of the light-emitting device 1 indicated by the cross-sectional line in FIG. 14 are aligned with the XYZ directions of the light-emitting module 901.

In a top view, the lower surface 11B of one or each of the light-emitting devices 1 is mounted on the wiring substrate 101 so as to overlap with at least a part of the heat dissipation portion 101D, at least a part of the electrode portion 101E, and at least a part of the insulating portion 101F. When the light-emitting device 1 is mounted on the wiring substrate 101 as mentioned above, it is important in some cases that the insulating portion 101F provide insulation between the heat dissipation portion 101D and the electrode portion 101E.

In the light-emitting device 1, the one or more light-emitting elements 20 are disposed in the internal space of the package 10. The one or more light-emitting elements 20 are disposed on the first upper surface 11A of the light-emitting device 1. The one or more light-emitting elements 20 emit light in a predetermined direction. One or each of the light-emitting elements 20 emits light that travels in the first direction. In the light-emitting device 1, the plurality of light-emitting elements 20 can be disposed to be arranged side by side in a second direction perpendicular to the first direction.

The one or each of the light-emitting elements 20 is disposed on the upper surface 31A of the submount 30. The one or each of the light-emitting elements 20 is disposed on the first upper surface 11A of the package 10 via the submount 30. The one or each of the light-emitting elements 20 is bonded to the wiring layer 33 of the submount 30.

The one or each of the light-emitting elements 20 generates heat accompanied by the emission of light. This heat is transferred to the base portion 11M of the package 10 via the submount 30, and further transferred to the heat dissipation portion 101D of the wiring substrate 101. Therefore, the heat dissipation portion 101D serves as a heat dissipation path for heat generated from the one or more light-emitting elements 20.

The one or more light-emitting elements 20 are electrically connected to the wiring portions 12A of the package 10 by the plurality of wiring lines 60. The plurality of wiring lines 60 include a wiring line 60 bonded to the one or more first wiring portions 12A1 provided on the upper surface 11G of the step portion 11F.

The electrode portion 101E of the wiring substrate 101 is electrically connected to the light-emitting device 1. The electrode portion 101E is bonded to the second wiring portion 12A2 of the light-emitting device 1 via a conductive adhesive. Thus, the one or more light-emitting elements 20 are electrically connected to the wiring substrate 101 through the wiring lines 60 and the wiring portions 12A.

The base portion 11M plays a role of dissipating heat generated from the light-emitting elements 20, and the frame portion 11N plays a role of electrically connecting the light-emitting elements 20 to the wiring substrate 101. Therefore, the base portion 11M of the package 10 is bonded to the heat dissipation portion 101D of the wiring substrate 101, and the frame portion 11N of the package 10 is bonded to the electrode portions 101E of the wiring substrate 101. The heat dissipation portion 101D is not electrically connected to the light-emitting device 1.

The lower surface 11B of the package 10 includes a first region serving as the lower surface of the base portion 11M and a second region serving as the lower surface of the frame portion 11N. The first region of the lower surface 11B overlaps with the heat dissipation portion 101D in a top view, and the second region overlaps with the electrode portions 101E in a top view. The one or more light-emitting elements 20 are disposed at a position overlapping with the first region of the lower surface 11B in a top view. Thus, it is possible to realize the light-emitting module 901 that efficiently combines a wiring function and a heat dissipation function.

For example, when forming the heat dissipation member 111 by press processing, the greater the height from the second upper surface 111B to the first upper surface 111A is, the poorer the flatness of the first upper surface 111A becomes, which might adversely affect the heat dissipating property. Therefore, configuring the wiring substrate 101 such that the first upper surface 111A of the heat dissipation member 111 is lower than the upper surface 122A of the electrode member 121 can contribute to improving the heat dissipating property.

The one or more second wiring portions 12A2 are provided in the second region of the lower surface 11B. The one or more second wiring portions 12A2 are provided on each of the side on which the first step portion 11F1 of the base 11 is disposed and the side on which the second step portion 11F2 is disposed.

In the second region of the lower surface 11B, the second wiring portion 12A2 provided in the region on the side on which the first step portion 11F1 is disposed is bonded to the first electrode member 121A of the wiring substrate 101, and the second wiring portion 12A2 provided in the region on the side on which the second step portion 11F2 is disposed is bonded to the second electrode member 121B of the wiring substrate 101.

In the light-emitting device 1, the one or more reflective members 40 are disposed in the internal space of the package 10. The one or more reflective members 40 are disposed on the first upper surface 11A of the package 10. One or each of the reflective members 40 reflects light emitted from at least one light-emitting element 20 by the light-reflective surface 41B.

The light reflected by the reflective member 40 travels upward, passes through the lid body 14, and is emitted to the outside of the package 10. In each of the plurality of light-emitting elements 20, light emitted from the light-emitting element 20 does not overlap with light emitted from any of the other light-emitting elements 20 on the upper surface 14A of the package 10.

The light emitted from the plurality of light-emitting elements 20 forms a plurality of light-emitting regions spaced apart from each other and arranged in the slow axis direction of the light on the upper surface 14A of the package 10. The respective light-emitting regions correspond to light emitted from mutually different light-emitting elements 20.

In the light-emitting device 1, the plurality of reflective members 40 can be disposed side by side in the second direction. The plurality of reflective members 40 are disposed such that the light-emitting surfaces 22 of the plurality of light-emitting elements 20 and the light-reflective surfaces 41B of the plurality of reflective members 40 face each other.

In the light-emitting device 1, the one or more protective elements 50 are disposed in the internal space of the package 10. One or each of the protective elements 50 is disposed on the upper surface 31A of the submount 30. The one or more protective elements 50 are electrically connected to the one or more light-emitting elements 20 by the plurality of wiring lines 60. The one or each of the protective elements 50 protects the light-emitting element 20.

In the light-emitting device 1, the optical member 70 is disposed on the upper surface 14A of the package 10. The optical member 70 is bonded to the package 10 via an adhesive. Light emitted from the light-emitting element 20 and emitted to the outside of the package 10 is incident on the optical member 70. The light incident on the optical member 70 is imparted an optical action by the optical active surface and is emitted from the optical member 70.

The light incident on each of the plurality of lens surfaces 71D provided to the optical member 70 is light emitted from mutually different light-emitting elements 20. The optical member 70 has the plurality of lens surfaces 71D corresponding to the plurality of light-emitting elements 20, respectively. The light emitted from one or each of the light-emitting elements 20 is collimated by the optical member 70 and emitted from the optical member 70.

In the light-emitting module 901, the connector 201 is mounted on the upper surface 101A of the wiring substrate 101. In addition, in the light-emitting module 901, the thermistor 301 is mounted on the upper surface 101A of the wiring substrate 101.

The connector 201 is electrically connected to the light-emitting device 1 mounted on the wiring substrate 101. By inserting a wiring terminal connected to an external power source into the connector 201, power can be supplied from the external power source to the light-emitting device 1. The thermistor 301 is not electrically connected to the light-emitting device 1 but electrically connected to the connector 201.

The connector 201 is bonded to an electrode member 121 to which the light-emitting device 1 is bonded. The connector 201 is bonded to an electrode member 121 to which the thermistor 301 is bonded. The electrode member 121 to which the thermistor 301 is bonded is different from the electrode member 121 to which the light-emitting device 1 is bonded.

In a top view, the distance from the first upper surface 111A of the heat dissipation member 111 to the first electrode member 121A is shorter than the distance from the first upper surface 111A to the electrode member 121 to which the thermistor 301 is bonded. In a top view, the first electrode member 121A is disposed between the first lateral surface 111C of the heat dissipation member 111 and the lateral surface 122B of the electrode member 121 to which the thermistor 301 is bonded opposite the first lateral surface 111C.

### SECOND EMBODIMENT

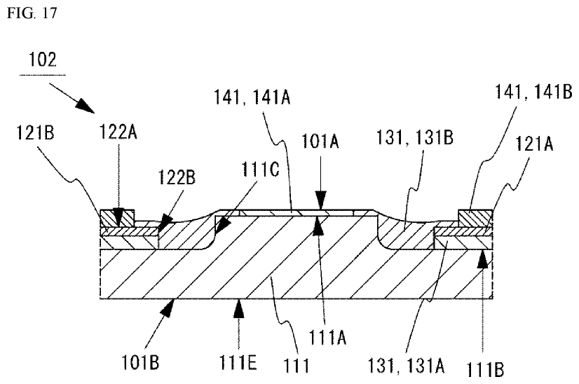

A light-emitting module 902 according to a second embodiment will be described. FIGS. 1 to 15A and FIGS. 16A to 17 are drawings for describing an exemplary form of the light-emitting module 902. FIG. 1 is a perspective view of the light-emitting module 902. FIG. 2 is a perspective view of the light-emitting device 1. FIG. 3 is a side view of the light-emitting device 1. FIG. 4 is a cross-sectional view of the light-emitting device 1 taken along line IV-IV in FIG. 2. FIG. 5 is a perspective view illustrating components disposed in the internal space of the light-emitting device 1. FIG. 6 is a top view of the state in FIG. 5. Note that, in FIG. 6, the wiring lines 60 illustrated in FIG. 5 are omitted. FIG. 7 is a perspective view of the package 10 of the light-emitting device 1. FIG. 8 is a cross-sectional view of the package 10 taken along line VIII-VIII in FIG. 7. FIG. 9 is a top view of the base 11 of the package 10. FIG. 10 is a bottom view of the base 11. FIG. 11 is a cross-sectional view of the base 11 taken along line XI-XI in FIG. 9. FIG. 12 is a top view of a state in which the light-emitting element 20 and the protective element 50 are disposed on the submount 30. FIG. 13 is a side view of the state in FIG. 12. FIG. 14 is a top view of a wiring substrate 102. FIG. 15A is a cross-sectional view of a wiring substrate to be compared with the wiring substrate 102. FIG. 16A is a top view of a state in which the heat dissipation member 111 (one example of the second mounting portion in this embodiment) is prepared for manufacturing the wiring substrate 102. FIG. 16B is a top view of a state in which the first insulating members 131A and the electrode members 121 (one example of the first mounting portion in this embodiment) are disposed on the heat dissipation member 111 for manufacturing the wiring substrate 102. FIG. 17 is a cross-sectional view of the wiring substrate 102, and a cross-sectional view taken along line XVII-XVII in FIG. 14. Note that, in FIG. 17, the first upper surface 111A of the heat dissipation member 111 and the electrode members 121 disposed around the first upper surface 111A are mainly illustrated, and a cross-sectional view taken along line XVII-XVII over the entire length of the wiring substrate 102 is not illustrated. Note that FIGS. 14 and 17 relate to the manufacture of the wiring substrate 102, and can be said to be a top view and a cross-sectional view of a state in which the second insulating member 131B (one example of the insulating portion in this embodiment) and the metal layers 141 are further disposed on the substrate shown in the state of FIG. 16B.

All content in the descriptions related to the light-emitting device 1 and the respective components of the first embodiment described above applies to the description of the light-emitting module 902 except for the content that can be said to be inconsistent from the drawings of FIGS. 1 to 15A and FIGS. 16A to 17 related to the light-emitting module 902. All non-contradictory content will not be repeated here in order to avoid duplication.

### Wiring Substrate 102

The first upper surface 111A of the heat dissipation member 111 (one example of the second upper surface of the second mounting portion in this embodiment) is at a position higher than the position of the upper surface 122A of one or each of the electrode members 121 (one example of the first upper surface of the first mounting portion in this embodiment). The first upper surface 111A is higher than the upper surface 122A by an amount in a range from 30 μm to 150 μm.

FIG. 17 schematically illustrates the shape of the second insulating member 131B formed when a height difference is provided between the first upper surface 111A and the upper surface 122A. A solder resist is used for the second insulating member 131B.

In FIG. 17, in the second insulating member 131B, an inclined surface is formed so as to rise from a lower side to a higher side between the first upper surface 111A and the upper surface 122A. Also, a dent is less likely to be generated than in FIG. 15A. Thus, compared with the former shape in which a dent is generated, the latter shape in which an inclined surface is formed is relatively less likely to generate a portion in which the thickness from the heat dissipation member 111 or from the electrode member 121 is reduced. Therefore, it can be said that the latter is a structure in which a defect in the insulating property due to manufacturing variation is less likely to occur.

The second insulating member 131B includes a first portion provided on the upper surface 122A, a second portion provided on the first upper surface 111A, and a third portion provided between the upper surface 122A and the first upper surface 111A.

In the wiring substrate 102, the second metal layer 141B is thicker than the first metal layer 141A.

The upper surface 122A of the first electrode member 121A provided on the second upper surface 111B in the second step is at a position lower than the position of the first upper surface 111A of the heat dissipation member 111. The upper surface 122A of the second electrode member 121B provided on the second upper surface 111B in the second step is at a position lower than the position of the first upper surface 111A of the heat dissipation member 111.

The first step and the second step may be replaced with a step of preparing a base material including the one or more electrode members 121 having the upper surface 122A and the heat dissipation member 111 spaced apart from the upper surface 122A and having the first upper surface 111A at a position higher than the position of the upper surface 122A.

### Light-Emitting Module 902

Since the second insulating member 131B is provided in a part of the first upper surface 111A of the heat dissipation member 111, the area of the first metal layer 141A in a top view is smaller than the area of the first upper surface 111A. Therefore, suppressing the thickness of the first metal layer 141A allows a greater contribution to the improvement of the heat dissipating property in some cases, and it is more preferable in some cases to locate the first upper surface 111A of the heat dissipation member 111 at a position higher than the position of the upper surface 122A of the electrode member 121.

The first embodiment and the second embodiment have been embodiments in which a specific example is the light-emitting module in which the mounting target on the wiring substrate 101 and the wiring substrate 102 is the light-emitting device 1. However, embodiments according to the present invention need not be limited to a wiring substrate and a light-emitting device. The wiring substrate 101 and the wiring substrate 102 are examples of a mounting substrate, and the light-emitting device 1 is an example of a component mounted on the mounting substrate. The present invention described by the first embodiment and the second embodiment can be applied to a module including a mounting substrate and one or more components mounted on the mounting substrate.

Therefore, the light-emitting device 1 is an example of a mounting member. The wiring substrate 101 is an example of a mounting substrate. The heat dissipation portion 101D is an example of a mounting portion, and the electrode portion 101E is an example of another mounting portion. The heat dissipation member 111 is an example of a mounting member, and the electrode member 121 is an example of another mounting member. At least a part of the mounting portion or a part of the mounting member is to be insulated by the insulating portion 101F.

Although each embodiment according to the present invention has been described above, the mounting substrate and the module according to the present invention is not strictly limited to the mounting substrate and the module in each embodiment. In other words, the present invention can be realized without being limited to the outer shape or the structure of the mounting substrate or the module disclosed by each embodiment. The present invention can be applied without requiring all the components being provided. For example, in a case in which some of the components of the mounting substrate and the module disclosed by the embodiments are not stated in the scope of the claims, the degree of freedom in design by those skilled in the art, such as substitutions, omissions, shape modifications, and material changes for those components, is allowed, and based thereon the invention stated in the scope of the claims being applied to those components is specified.

The light-emitting module described in the embodiments can be used in a projector. That is, the projector can be said to be one form of usage to which the present invention is applied. Note that the present invention is not limited thereto, and can be used in various applications, such as projectors, lighting, exposure, on-vehicle headlights, head-mounted displays, backlights of other displays, and the like. Moreover, the mounting substrate and the module described in the embodiments can be used in various applications other than the above-described applications.

What is claimed is:

1. A light-emitting module comprising:
a mounting substrate including
a first mounting portion having a first upper surface,
a second mounting portion spaced apart from the first upper surface and having a second upper surface at a position higher than a position of the first upper surface, and
an insulating portion arranged between the first upper surface and the second upper surface, the insulating portion covering only a part of a region of the first upper surface, only a part of a region of the second upper surface, and a region between the first upper surface and the second upper surface; and
a light-emitting device having a lower surface mounted on the mounting substrate so as to overlap with at least a part of the first mounting portion, at least a part of the second mounting portion, and at least a part of the insulating portion in a top view.

2. The light-emitting module according to claim 1, wherein
the light-emitting device includes one or more light-emitting elements and a package in which the one or more light-emitting elements are disposed,
the package has an upper surface on which the one or more light-emitting elements are disposed, the package defining the lower surface of the light-emitting device,
the lower surface of the light-emitting device has a first region overlapping with the first mounting portion and a second region overlapping with the second mounting portion in the top view, and
the one or more light-emitting elements are disposed at a position overlapping with the first region in the top view.

3. The light-emitting module according to claim 1, wherein
the first mounting portion is a heat dissipation member configured to serve as a heat dissipation path for heat generated from the light-emitting device, and
the second mounting portion is an electrode member electrically connected to the light-emitting device.

4. The light-emitting module according to claim 3, further comprising:
a first metal layer arranged on the first upper surface of the first mounting portion; and
a second metal layer arranged on the second upper surface of the second mounting portion, wherein
the first metal layer is thicker than the second metal layer.

5. The light-emitting module according to claim 1, wherein
the first mounting portion is an electrode member electrically connected to the light-emitting device, and
the second mounting portion is a heat dissipation member configured to serve as a heat dissipation path for heat generated from the light-emitting device.

6. The light-emitting module according to claim 5, further comprising:
a first metal layer arranged on the first upper surface of the first mounting portion; and
a second metal layer arranged on the second upper surface of the second mounting portion, wherein
the first metal layer is thicker than the second metal layer.

7. The light-emitting module according to claim 1, wherein
the insulating portion includes a first portion arranged on the part of the region of the first upper surface, a second portion arranged on the part of the region of the second upper surface, and a third portion arranged between the first upper surface and the second upper surface,
an upper surface of the second portion is higher than an upper surface of the first portion,
an upper surface of the third portion has an inclined surface region extending from an upper surface side of the first portion toward an upper surface side of the second portion, and
the upper surface of the third portion is level with or higher than the upper surface of the first portion.

8. The light-emitting module according to claim 1, wherein
the second upper surface is higher than the first upper surface by an amount in a range from 30 μm to 150 μm.

9. The light-emitting module according to claim 1, wherein
a distance from the first upper surface to the second upper surface is in a range from 100 μm to 300 μm in the top view.

10. A mounting substrate comprising:
a first mounting portion having a first upper surface;
a second mounting portion spaced apart from the first upper surface and having a second upper surface at a position higher than a position of the first upper surface; and
an insulating portion arranged between the first upper surface and the second upper surface, the insulating portion covering only a part of a region of the first upper surface, only a part of a region of the second upper surface, and a region between the first upper surface and the second upper surface.

11. A manufacturing method of a mounting substrate comprising:
preparing a base material including a first mounting portion having a first upper surface and a second mounting portion spaced apart from the first upper surface and having a second upper surface at a position higher than a position of the first upper surface; and
providing an insulating portion between the first upper surface and the second upper surface, the insulating portion covering only a part of a region of the first upper surface, only a part of a region of the second upper surface, and a region between the first upper surface and the second upper surface.
